(19) United States
(12) Patent Application Publication
(10) Pub. No.: US 2023/0324728 A1
(43) Pub. Date: Oct. 12, 2023

(54) OPTICAL PATH CONTROL MEMBER AND DISPLAY DEVICE COMPRISING SAME

(71) Applicant: LG INNOTEK CO., LTD., Seoul (KR)

(72) Inventors: Chan Mi JU, Seoul (KR); Byung Sook KIM, Seoul (KR)

(21) Appl. No.: 18/043,488

(22) PCT Filed: Sep. 3, 2021
(86) PCT No.: PCT/KR2021/011903

§ 371 Date: Feb. 28, 2023

(30) Foreign Application Priority Data
Sep. 3, 2020 (KR) 10-2020-0112115

(51) Int. Cl. G02F 1/13; G02F 1/167; H10K 59/50; G02F 1/1335

(52) U.S. Cl. CPC G02F 1/1323; G02F 1/167; G02F 2001/1678; G02F 1/1335; H10K 59/50

(57) ABSTRACT

An optical path control member according to an embodiment comprises: a first substrate; a first electrode arranged on the first substrate; a second substrate arranged on the first substrate; a second electrode arranged below the second substrate; and a light conversion unit arranged between the first electrode and the second electrode, wherein the light conversion unit includes a partition part and accommodation parts, each accommodation part includes a dispersion liquid and light conversion particles dispersed in the dispersion liquid, the accommodation parts operate in a public mode or a privacy mode according to whether a voltage is applied thereto, the public mode includes the steps of applying an initial positive voltage and applying a positive sustaining voltage, the privacy mode includes a step of applying a negative voltage, the steps of applying the initial positive voltage, applying the positive sustaining voltage, and applying the negative voltage are sequentially performed, and the magnitude of the initial positive voltage is greater than that of the positive sustaining voltage.

### TECHNICAL FIELD

An embodiment relates to an optical path control member, and to a display device including the same.

### BACKGROUND ART

A light blocking film blocks transmitting of light from a light source, and is attached to a front surface of a display panel which is a display device used for a mobile phone, a notebook, a tablet PC, a vehicle navigation device, a vehicle touch, etc., so that the light blocking film adjusts a viewing angle of light according to an incident angle of light to express a clear image quality at a viewing angle needed by a user when the display transmits a screen.

In addition, the light blocking film may be used for the window of a vehicle, building or the like to shield outside light partially to prevent glare, or to prevent the inside from being visible from the outside.

That is, the light blocking film may be an optical path control member that controls the movement path of light to block light in a specific direction and transmit light in a specific direction. Accordingly, it is possible to control the viewing angle of the user by controlling a transmission angle of the light by the light blocking film.

Meanwhile, such a light blocking film may be divided into a light blocking film that can always control the viewing angle regardless of the surrounding environment or the user's environment and a switchable light blocking film that allow the user to turn on/off the viewing angle control according to the surrounding environment or the user's environment.

Such a switchable light blocking film may be implemented by converting a accommodating portion of a light conversion unit into a light transmitting part and a light blocking part by filling the inside of the accommodating portion with light conversion material including particles that may move when a voltage is applied and a dispersion liquid for dispersing the particles and by dispersing and aggregating the particles.

For example, by applying a positive voltage, negatively charged particles may be moved in the direction of the electrode to drive the accommodating part to the light transmitting part, and by applying a negative voltage, the particles may be again dispersed into the dispersion liquid and converted into a light blocking part.

At this time, when the positive voltage increases, the moving speed of the light conversion particles increases, but the light conversion particles are agglomerated due to the stress transmitted to the light conversion particles, so that the particle diameter of the light conversion particles increases, and thereby there is a problem in that light transmittance is reduced when the optical path control member is driven as the light transmission part.

In addition, when the positive voltage decreases, the moving speed of the light conversion particles decreases, and thus the driving speed of the optical path control member decreases, and thereby there is a problem in that light transmittance is reduced when the optical path control member is driven as the light transmission part.

Accordingly, the optical path control member having a new structure capable of solving the above problems is required.

### DISCLOSURE

### Technical Problem

An embodiment relates to an optical path control member having improved reliability and driving characteristics.

### Technical Solution

An optical path control member according to an embodiment includes: a first substrate; a first electrode disposed on the first substrate; a second substrate disposed on the first substrate; a second electrode disposed under the second substrate; and a light conversion unit disposed between the first electrode and the second electrode, the light conversion unit includes a partition wall portion and an accommodating portion, the accommodating portion includes a dispersion liquid and light conversion particles dispersed in the dispersion liquid, the accommodating portion is driven in a public mode or a privacy mode depending on whether voltage is applied or not, the public mode includes applying an initial positive voltage and applying a holding positive voltage, the privacy mode includes applying a negative voltage, a step of applying the initial positive voltage, a step of applying the holding positive voltage, and the step of applying the negative voltage are sequentially performed, the magnitude of the initial positive voltage is greater than that of the holding positive voltage.

### Advantageous Effects

The optical path control member according to the embodiment may include applying voltages having different level when driving the public mode by applying voltages.

In detail, it may include applying an initial voltage and applying a holding voltage.

That is, by first applying an initial voltage greater than the level of the holding voltage to the optical path control member according to the embodiment, the optical path control member is rapidly driven to a transmittance close to the target transmittance, and then the public mode of the target transmittance may be driven by reducing the voltage to a holding voltage with a relatively small voltage.

Accordingly, since the public mode is driven with a low voltage holding voltage, stress of the light conversion particles caused by the high voltage may be reduced, and thereby minimizing the agglomeration of the light conversion particles.

Accordingly, the public mode can be driven with a uniform transmittance for a long time without a decrease in transmittance in the public mode.

In addition, since the transmittance is rapidly changed by the initial voltage, it is possible to prevent the driving time from being delayed by the low voltage.

That is, the optical path control member according to the embodiment may prevent agglomeration of light conversion particles by the holding voltage having a low voltage while driving time is reduced by the initial voltage having a high voltage, and thereby the driving characteristics, driving speed and reliability of the optical path control member can be improved.

In addition, the optical path control member according to the embodiment may include applying a rest voltage having 0V for a predetermined period of time between the privacy mode and the public mode.

Accordingly, since stress of the light conversion particles accumulated in the public mode and the privacy mode is reduced, agglomeration of the light conversion particles may be prevented.

Accordingly, even if the optical path control member is repeatedly driven in the public mode and the privacy mode, it may be used without reducing the light transmittance, and thereby, the life of the optical path control member may be improved.

### DESCRIPTION OF DRAWINGS

FIG. 1 is a perspective view of an optical path control member according to an embodiment.

FIGS. 2 and 3 are cross-sectional views taken along area A-A′ of FIG. 1.

FIG. 4 is a view for explaining a driving method according to a voltage level of the optical path control member according to the embodiment.

FIGS. 5 and 6 are views for explaining the light transmittance according to the voltage level in the optical path control member according to the embodiment.

FIGS. 7 to 9 are views for explaining changes in light transmittance of optical path control members according to examples and comparative examples.

FIGS. 10 and 11 are views for explaining a change in light transmittance depending on whether or not a rest voltage of the optical path control member according to examples and comparative examples is applied.

FIGS. 12 and 13 are cross-sectional views of a display device to which the optical path control member according to the embodiment is applied.

FIGS. 14 to 16 are views for explaining one embodiment of the display device to which the optical path control member according to the embodiment is applied.

### MODES OF THE INVENTION

Hereinafter, embodiments of the present invention will be described in detail with reference to the accompanying drawings. However, the spirit and scope of the present invention is not limited to a part of the embodiments described, and may be implemented in various other forms, and within the spirit and scope of the present invention, one or more of the elements of the embodiments may be selectively combined and replaced.

In addition, unless expressly otherwise defined and described, the terms used in the embodiments of the present invention (including technical and scientific terms) may be construed the same meaning as commonly understood by one of ordinary skill in the art to which this invention belongs, and the terms such as those defined in commonly used dictionaries may be interpreted as having a meaning that is consistent with their meaning in the context of the relevant art.

In addition, the terms used in the embodiments of the present invention are for describing the embodiments and are not intended to limit the present invention. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present invention, the terms such as first, second, A, B, (a), and (b) may be used. These terms are only used to distinguish the elements from other elements, and the terms are not limited to the essence, order, or order of the elements.

In addition, when an element is described as being “connected”, or “coupled” to another element, it may include not only when the element is directly “connected” to, or “coupled” to other elements, but also when the element is “connected”, or “coupled” by another element between the element and other elements.

Further, when described as being formed or disposed “on (over)” or “under (below)” of each element, the “on (over)” or “under (below)” may include not only when two elements are directly connected to each other, but also when one or more other elements are formed or disposed between two elements.

Furthermore, when expressed as “on (over)” or “under (below)”, it may include not only the upper direction but also the lower direction based on one element.

Hereinafter, an optical path control member according to an embodiment will be described with reference to drawings.

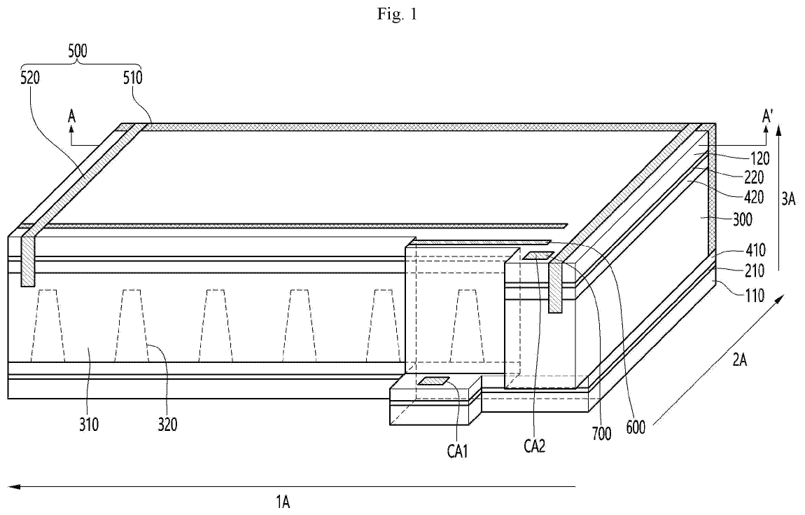

FIG. 1 is a perspective view of an optical path control member according to a embodiment.

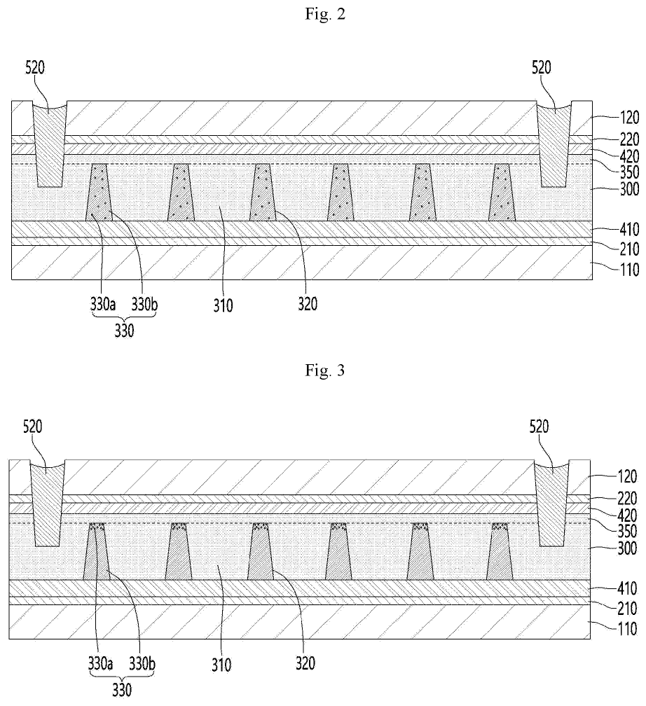

Referring to FIGS. 1 and 2, the optical path control member 1000 according to the embodiment may include a first substrate 110, a second substrate 120, a first electrode 210, a second electrode 220, and a light conversion unit 300.

The light conversion unit 300 may be disposed between the first substrate 110 and the second substrate 120. In detail, the light conversion unit 300 may be disposed between the first electrode 210 and the second electrode 220.

An adhesive layer 410 may be disposed between the light conversion unit 300 and the first electrode 210. For example, a transparent adhesive layer capable of transmitting light may be disposed between the light conversion unit 300 and the first electrode 210. For example, the adhesive layer 410 may include an optically clear adhesive (OCA).

In addition, a buffer layer 420 may be disposed between the light conversion unit 300 and the second electrode 220. Accordingly, adhesion between the light conversion unit 300 and the first electrode 210, which are different materials, may be improved.

The light conversion unit 300 and the second electrode 220 may be bonded by the buffer layer 420.

FIGS. 2 and 3 are cross-sectional views taken along area A-A′ of FIG. 1.

Referring to FIGS. 2 and 3, the light conversion unit 300 may include a plurality of partition wall portions 310, a plurality of accommodating portions 320, and a base portion 350.

Each of the partition wall portion 310 and the accommodating portion 320 may include a plurality of numbers, and the partition wall portion 310 and the accommodating portion 320 may be alternately disposed. That is, one accommodating portion 320 may be disposed between two adjacent partition wall portions, and one partition wall portion 310 may be disposed between the two adjacent accommodating portions.

The base portion 350 may be disposed on the accommodating portion 320. In detail, the base portion 350 may be disposed between the accommodating portion 320 and the buffer layer 420. Accordingly, the light conversion unit 300 may be adhered to the second electrode 220 by the base portion 350 and the buffer layer 420.

The base portion 350 is a region formed during an imprinting process for forming the partition wall portion 310 and the accommodating portion 320, and may include the same material as the partition wall portion 310.

The partition wall portion 310 may transmit light. In addition, light transmittance of the accommodating portion 320 may be changed by applying a voltage.

In detail, a light conversion material 330 may be disposed inside the accommodating portion 320. The light transmittance of the accommodating portion 320 may be changed by the light conversion material 330. The light conversion material 330 may include light conversion particles 330b moved by application of a voltage and a dispersion liquid 330a dispersing the light conversion particles 330b. In addition, the light conversion material 330 may further include a dispersing agent that prevents aggregation of the light conversion particles 330b.

By applying the voltage, the light conversion particles 330b inside the dispersion liquid 330a may be moved. For example, referring to FIG. 2, a surfaces of the light conversion particles 330b inside the dispersion liquid 330a are negatively charged, and when a positive voltage is applied from the first electrode 210 and the second electrode 220, the light conversion particles 330b move toward the first electrode 210 or the second electrode 220, and thereby the accommodating portion 320 may become a light transmitting part.

Also, referring to FIG. 3, when a negative voltage is applied from the first electrode 210 and the second electrode 220, the light conversion particles 330b are again dispersed into the dispersion liquid 330a, and thereby the accommodating portion 320 may become a light blocking part.

Meanwhile, when the positive voltage increases, the moving speed of the light conversion particles increases, but the light conversion particles are agglomerated due to the stress transmitted to the light conversion particles, so that the particle diameter of the light conversion particles increases, and thereby there is a problem in that light transmittance is reduced when the optical path control member is driven as the light transmission part.

In addition, when the positive voltage decreases, the moving speed of the light conversion particles decreases, and thus the driving speed of the optical path control member decreases, and thereby there is a problem in that light transmittance is reduced when the optical path control member is driven as the light transmission part.

Accordingly, the optical path controller according to the embodiment controls the driving method of the voltage applied to the accommodating portion to improve the driving speed while preventing the agglomeration of the light conversion particles.

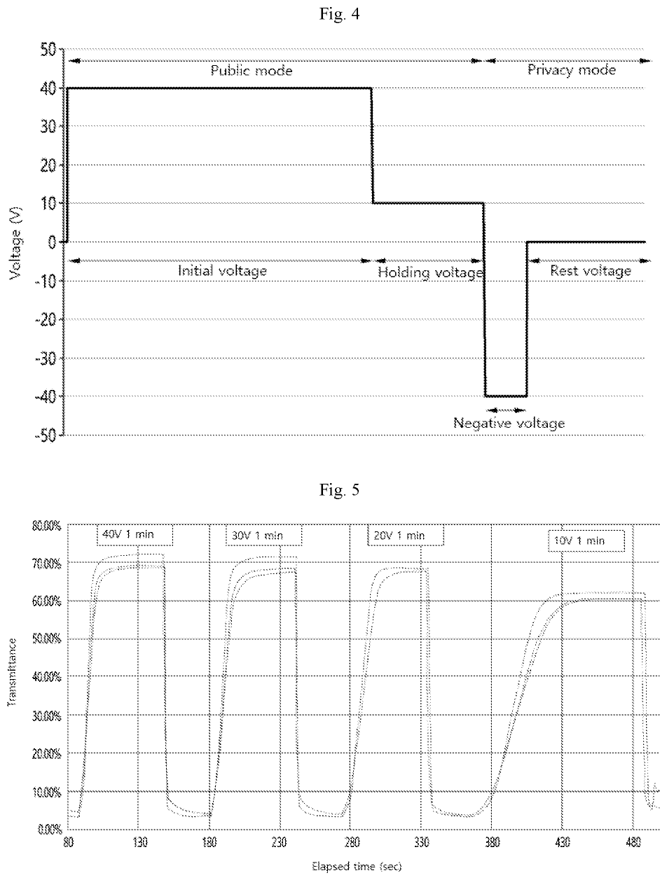

Referring to FIG. 4, the optical path control member according to the embodiment may be driven in the order of an initial mode, a public mode, and a privacy mode. The initial mode, the public mode, and the privacy mode may be sequentially driven. That is, the public mode and the privacy mode may be sequentially driven in one cycle, and the cycle may be repeated according to a user's use environment.

The initial mode is a state in which the optical path control member is initially turned on, and the light conversion particles are dispersed inside the dispersion liquid, and a state of the light conversion particle in the initial mode may be the same as a state of the light conversion particle in the privacy mode. The public mode is a state in which the light conversion particles are moved toward the first electrode or the second electrode, and the privacy mode is a state in which the light conversion particles are dispersed in the dispersion liquid.

In the initial mode, voltage may not be applied. That is, in the initial mode, no voltage is applied from the first electrode 210 and the second electrode 220. Accordingly, the light conversion particles 330b may be dispersed and disposed inside the dispersion liquid 330a. Therefore, in the initial mode, the accommodating portion may be driven as a light blocking unit. That is, the initial mode may correspond to the privacy mode.

That is, the initial mode may be a mode before the optical path control member is driven.

In the public mode, voltage may be applied. In detail, in the public mode, a positive voltage or a negative voltage may be applied. When the positive voltage is applied in the public mode, the negative voltage is applied in the privacy mode, and when the negative voltage is applied in the public mode, the positive voltage is applied in the privacy mode. That is, the public mode and the privacy mode may apply opposite voltages.

Hereinafter, for convenience of description, a case in which the positive voltage is applied in the public mode will be mainly described.

That is, in the public mode, the positive voltage is applied from the first electrode 210 and the second electrode 220. Accordingly, the light conversion particles 330b may move toward the first electrode 210 or the second electrode 220. Therefore, in the public mode, the accommodating portion 320 may be driven as a light transmitting part.

The public mode may include applying an initial positive voltage and applying a holding positive voltage. In detail, in the public mode, after the initial positive voltage is applied, the holding positive voltage may be applied.

In the step of applying the initial positive voltage, a relatively large voltage is applied to reduce the driving time of the optical path control member, and in the step of applying the holding positive voltage, a relatively small voltage may be applied to reduce reliability and power consumption of the optical path control member.

In detail, the initial positive voltage may be greater than the holding positive voltage. Accordingly, a maximum light transmittance at the initial positive voltage may be different from a maximum light transmittance at the holding positive voltage. That is, the maximum light transmittance at the initial positive voltage may be greater than the maximum light transmittance at the holding positive voltage.

The maximum light transmittance may be defined as the maximum light transmittance among cases in which the change in light transmittance is 1% or less for 1 minute after application of the positive voltage.

In the step of applying the initial positive voltage, the initial positive voltage may be applied for a time when the light transmittance close to the maximum light transmittance when the holding positive voltage is applied is reached. That is, the application time of the initial positive voltage may be defined as a time until the light transmittance by the initial positive voltage becomes close to the maximum light transmittance of the holding positive voltage.

Accordingly, the light transmittance according to the application time of the initial positive voltage may be equal to or different from the maximum light transmittance when the holding positive voltage is applied. That is, the light transmittance according to the application time of the initial positive voltage may be equal to, greater than, or less than the maximum light transmittance when the holding positive voltage is applied.

In detail, the application time of the initial positive voltage may be defined as a time until light transmittance by the initial positive voltage becomes 70% to 130% of the maximum light transmittance of the holding positive voltage. In more detail, the application time of the initial positive voltage may be defined as a time until light transmittance by the initial positive voltage becomes 80% to 120% of the maximum light transmittance of the holding positive voltage. In more detail, the application time of the initial positive voltage may be defined as a time until light transmittance by the initial positive voltage becomes 90% to 110% of the maximum light transmittance of the holding positive voltage.

When the initial positive voltage is applied for a time when the light transmittance by the initial positive voltage is 70% or less of the maximum light transmittance of the holding positive voltage, after applying the holding positive voltage, the time required for the maximum light transmittance of the holding positive voltage is increased, and thereby since the change time of the light transmittance becomes long, the user's visibility and the driving speed of the optical path control member decrease.

When the initial positive voltage is applied for a time when the light transmittance by the initial positive voltage exceeds 130% of the maximum light transmittance of the holding positive voltage, after applying the holding positive voltage, the time for decreasing the sustain positive voltage to the maximum light transmittance becomes longer, and thereby since the change time of the light transmittance becomes long, the user's visibility and the driving speed of the optical path control member decrease.

Therefore, since the optical path control member according to the embodiment applies the initial positive voltage greater than the holding positive voltage until the transmittance becomes close to the maximum light transmittance of the holding positive voltage, in the step of applying the holding positive voltage, the time required to reach the maximum light transmittance of the holding positive voltage may be reduced.

Accordingly, the optical path control member according to the embodiment may have a fast-driving time with a small holding positive voltage.

After the initial positive voltage is applied until the light transmittance by the initial positive voltage becomes close to the maximum light transmittance of the holding positive voltage, the step of applying the holding positive voltage may proceed.

The holding positive voltage may be changed by a voltage according to a desired target transmittance. That is, when the target transmittance increases, the holding positive voltage may also increase, and when the target transmittance decreases, the holding positive voltage may also decrease.

The holding positive voltage may be smaller than the initial positive voltage. In detail, the magnitude of the holding positive voltage may be less than 100% of the magnitude of the initial positive voltage. In detail, the magnitude of the holding positive voltage may be 5% to 90% of the magnitude of the initial positive voltage. In more detail, the magnitude of the holding positive voltage may be 20% to 70% of the magnitude of the initial positive voltage. In more detail, the magnitude of the holding positive voltage may be 30% to 60% of the magnitude of the initial positive voltage. In more detail, the magnitude of the holding positive voltage may be 40% to 50% of the magnitude of the initial positive voltage.

Further, the holding positive voltage may have a magnitude such that a maximum light transmittance of the holding positive voltage is 70% or more of a maximum light transmittance of the initial positive voltage.

In detail, the holding positive voltage may have a magnitude in which the maximum light transmittance of the holding positive voltage is 70% to 99% of the maximum light transmittance of the initial positive voltage. In more detail, the holding positive voltage may have a magnitude in which the maximum light transmittance of the holding positive voltage is 80% to 90% of the maximum light transmittance of the initial positive voltage.

When the magnitude of the holding positive voltage is less than 5% of the magnitude of the initial positive voltage, the maximum light transmittance of the holding positive voltage may be too small, and thus the overall light transmittance of the optical path control member may decrease, resulting in reduced visibility.

In addition, when the magnitude of the sustain positive voltage has a light transmittance of 70% or more of the maximum light transmittance of the initial positive voltage, the maximum light transmittance of the holding positive voltage may be too small, and thus the overall light transmittance of the optical path control member may decrease, resulting in reduced visibility.

TABLE 1

| | | 40 V | 30 V | 20 V | 10 V |
|---|---|---|---|---|---|
| 1 | transmittance (%) | 68.90 | 67.69 | 67.69 | 60.33 |
| | Transmittance | | 96.24 | 98.24 | 87.56 |
| | compared to 40 V (%) | | | | |
| 2 | transmittance (%) | 69.12 | 68.57 | 67.80 | 60.55 |
| | Transmittance | | 99.20 | 98.09 | 87.60 |
| | compared to 40 V (%) | | | | |
| 3 | transmittance (%) | 72.00 | 71.54 | 68.46 | 61.98 |
| | Transmittance | | 99.36 | 95.08 | 86.08 |
| | compared to 40 V (%) | | | | |

TABLE 2

| | | 40 V | 10 V | 8 V | 5 V |
|---|---|---|---|---|---|
| 1 | transmittance (%) | 68.61 | 61.92 | 58.04 | 49.12 |
| | Transmittance | | 90.25 | 84.59 | 71.59 |
| | compared to 40 V (%) | | | | |
| 2 | transmittance (%) | 69.72 | 62.33 | 58.48 | 49.89 |
| | Transmittance | | 89.98 | 84.42 | 72.02 |
| | compared to 40 V (%) | | | | |
| 3 | transmittance (%) | 71.92 | 62.89 | 60.02 | 52.53 |
| | Transmittance | | 87.44 | 83.45 | 73.04 |
| | compared to 40 V (%) | | | | |

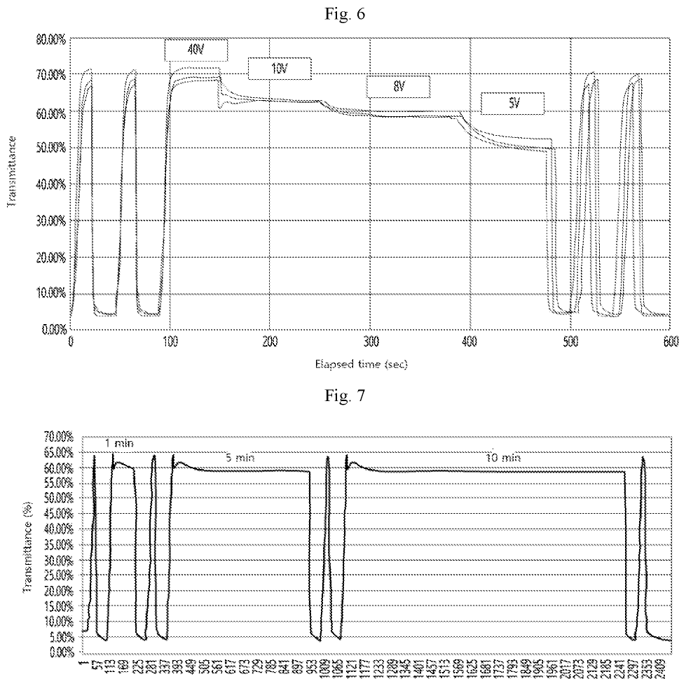

FIGS. 5 and 6 are views for explaining the relative light transmittance according to the magnitude of the holding positive voltage when the initial positive voltage is 40V. In addition, Table 1 is a table showing the light transmittance according to FIG. 5, and Table 2 is a table showing the light transmittance according to FIG. 6.

FIG. 5 and Table 1 are views for explaining light transmittance when positive voltages of 40V, 30V, 20V, and 10V are individually applied, and FIG. 6 and Table 2 are views for explaining light transmittance when positive voltages of 40V, 10V, 8V, and 5V are continuously applied.

Referring to FIG. 5 and Table 1, it can be seen that the light transmittance according to the positive voltage of 30V, 20V, and 10V has a light transmittance of 85% or more with respect to the light transmittance according to the positive voltage of 40V.

Referring to FIG. 6 and Table 2, it can be seen that the light transmittance according to the positive voltage of 10V, 8V, and 5V has a light transmittance of 70% or more with respect to the light transmittance according to the positive voltage of 40V

That is, referring to FIGS. 5 and 6 and Tables 1 and 2, since the sustain positive voltage has a magnitude of 5% or more of the initial positive voltage or the light transmittance according to the sustain positive voltage has a light transmittance of 70% or more with respect to the light transmittance of the initial positive voltage, the visibility of the optical path control member may be maintained.

In a section where the holding positive voltage is applied, a maximum light transmittance according to the holding positive voltage may be maintained.

For example, if the initial positive voltage is applied for a time to reach a light transmittance smaller than the maximum light transmittance of the holding positive voltage, in a section in which the holding positive voltage is applied, the light transmittance may increase up to the maximum light transmittance of the holding positive voltage, and then the light transmittance may be maintained.

In addition, if the initial positive voltage is applied for a time to reach the same light transmittance as the maximum light of the holding positive voltage, in the section where the holding positive voltage is applied, the light transmittance reached in the section where the initial positive voltage is applied may be maintained.

In addition, if the initial positive voltage is applied for a time to reach a light transmittance larger than the maximum light transmittance of the holding positive voltage, in a section in which the holding positive voltage is applied, the light transmittance may decrease up to the maximum light transmittance of the holding positive voltage, and then the light transmittance may be maintained.

Meanwhile, the step of applying the holding positive voltage may have a holding voltage of a plurality of magnitudes.

For example, the applying of the holding positive voltage may include a first holding positive voltage and a second holding positive voltage.

In detail, the magnitude of the first holding positive voltage may be smaller than the magnitude of the initial positive voltage, and the magnitude of the second holding positive voltage may be smaller than the magnitude of the first holding positive voltage.

That is, when the magnitude of the positive voltage corresponding to the target light transmittance is the second holding positive voltage, when the application time of the initial positive voltage increases, in the step of applying the initial positive voltage, a first light transmittance larger than the target light transmittance is reached, and, in the step of applying the holding positive voltage, the light transmittance may be decreased by the magnitude of the second sustain positive voltage and thereby changed to the second light transmittance that is the target light transmittance.

In this case, when the difference between the first light transmittance and the second light transmittance is large, a user's visibility may be reduced due to a rapid change in light transmittance. Accordingly, a sudden change in light transmittance due to a difference in light transmittance may be prevented by introducing the first positive holding voltage serving as a buffer between the initial positive voltage and the second holding positive voltage.

Alternatively, the first sustain positive voltage may be smaller than the initial positive voltage, and the second sustain positive voltage may be greater than the first sustain positive voltage.

That is, when the magnitude of the positive voltage corresponding to the target light transmittance is the second holding positive voltage, when the application time of the initial positive voltage decreases, in the step of applying the initial positive voltage, a first light transmittance smaller than the target light transmittance is reached, and, in the step of applying the holding positive voltage, the light transmittance may be increased by the magnitude of the second sustain positive voltage and thereby changed to the second light transmittance that is the target light transmittance.

In this case, when the difference between the first light transmittance and the second light transmittance is large, a user's visibility may be reduced due to a rapid change in light transmittance. Accordingly, a sudden change in light transmittance due to a difference in light transmittance may be prevented by introducing the first positive holding voltage serving as a buffer between the initial positive voltage and the second holding positive voltage.

In the privacy mode, voltage may be applied. In detail, a negative voltage or a positive voltage may be applied in the privacy mode. In detail, in the privacy mode, a voltage having a polarity opposite to that in the public mode may be applied. For example, when a positive voltage is applied in the public mode, a negative voltage is applied in the privacy mode, and when a negative voltage is applied in the public mode, a positive voltage is applied in the privacy mode. Hereinafter, for convenience of description, a case in which a negative voltage is applied in the privacy mode will be mainly described.

That is, in the privacy mode, a negative voltage is applied from the first electrode 210 and the second electrode 220. Accordingly, the light conversion particles 330b may be dispersed and disposed again into the dispersion liquid 330a. Therefore, in the privacy mode, the accommodating portion may be driven as a light blocking unit.

The privacy mode may include applying a negative voltage and applying the rest voltage. In detail, in the privacy mode, a negative voltage may be applied first and then the rest voltage may be applied.

The aforementioned steps of applying the initial positive voltage, applying the holding positive voltage, applying the negative voltage, and applying the rest voltage may be sequentially performed.

Applying the negative voltage is a step of moving the light conversion particles 330b. In detail, the negatively charged light conversion particles 330b may be dispersed again into the dispersion liquid 330a by application of the negative voltage.

In this case, the magnitude of the negative voltage may be the same as or different from the magnitude (absolute value) of the initial positive voltage. In detail, the magnitude of the negative voltage may be 80% to 120% of the magnitude of the initial positive voltage.

Accordingly, since the negative voltage is applied again at the magnitude of the initial positive voltage, the light conversion particles may be effectively dispersed.

Meanwhile, the step of applying the negative voltage may be driven by a pulse voltage. In detail, the step of applying the negative voltage may include a pulse voltage repeating a positive voltage and a negative voltage. The pulse voltage may be defined as a voltage for repeatedly applying a voltage having a period of time smaller than the voltage application time of the public mode.

Accordingly, the light conversion particles 330b are dispersed while repeatedly moving in the direction of the first electrode 210 and the direction of the second electrode 220 inside the dispersion liquid 330a by the application of the negative voltage, the light conversion particles 330b may be uniformly dispersed in the dispersion liquid 330a.

In the step of applying the rest voltage, a voltage of 0V may be applied. That is, the voltage may not be applied in the step of applying the rest voltage.

The applying of the rest voltage is a step of relieving stress of the light conversion particles. That is, when the positive and negative voltages are applied, the light conversion particles react with each other to gradually apply stress to the light conversion particles, and when the stress is repeatedly accumulated, the light conversion particles may be aggregated.

Therefore, the optical path control member according to the embodiment includes the step of applying a rest voltage and thus the step of stabilizing the light conversion particles 330b, and thereby, since stress accumulated in the light conversion particles 330b may be reduced, aggregation of the light conversion particles 330b may be prevented.

A time for applying the rest voltage may be equal to or longer than a time for applying the initial positive voltage. The step of applying the rest voltage may be 5 seconds or longer. In detail, the step of applying the rest voltage may be 10 seconds or longer. In detail, the step of applying the rest voltage may be 15 seconds or more. In detail, the step of applying the rest voltage may be 20 seconds or more. If the step of applying the rest voltage is less than 5 seconds, the stress accumulated in the light conversion particles 330b is not sufficiently reduced, and thus the light conversion particles 330b may agglomerate.

The optical path control member according to the embodiment may include applying voltages having different level when driving the public mode by applying voltages.

In detail, it may include applying an initial voltage and applying a holding voltage.

That is, by first applying an initial voltage greater than the level of the holding voltage to the optical path control member according to the embodiment, the optical path control member is rapidly driven to a transmittance close to the target transmittance, and then the public mode of the target transmittance may be driven by reducing the voltage to a holding voltage with a relatively small voltage.

Accordingly, since the public mode is driven with a low voltage holding voltage, stress of the light conversion particles caused by the high voltage may be reduced, and thereby minimizing the agglomeration of the light conversion particles.

Accordingly, the public mode can be driven with a uniform transmittance for a long time without a decrease in transmittance in the public mode.

In addition, since the transmittance is rapidly changed by the initial voltage, it is possible to prevent the driving time from being delayed by the low voltage.

That is, the optical path control member according to the embodiment may prevent agglomeration of light conversion particles by the holding voltage having a low voltage while driving time is reduced by the initial voltage having a high voltage, and thereby the driving characteristics, driving speed and reliability of the optical path control member can be improved.

In addition, the optical path control member according to the embodiment may include applying a rest voltage having 0V for a predetermined period of time between the privacy mode and the public mode.

Accordingly, since stress of the light conversion particles accumulated in the public mode and the privacy mode is reduced, agglomeration of the light conversion particles may be prevented.

Accordingly, even if the optical path control member is repeatedly driven in the public mode and the privacy mode, it may be used without reducing the light transmittance, and thereby, the life of the optical path control member may be improved.

Hereinafter, the present invention will be described in more detail through measurement of the transmittance of the optical path control member according to Examples and Comparative Examples. These embodiments are only presented as examples in order to explain the present invention in more detail. Therefore, the present invention is not limited to these examples.

Meanwhile, after measuring the luminance (A) of light emitted from a light source in a state in which the optical path control member is not disposed and the luminance (B) of light emitted from the light source through the optical path control member at an angle of 45° in a state in which the optical path control member is disposed on the light source, the light transmittance of the optical path control member described below is measured by calculating (B/A)*100.

### Example 1

After applying a positive voltage of +40V to the optical path control member in the initial mode to which no voltage is applied and reducing the voltage to a positive voltage of +10V to convert the optical path control member to public mode, and then the change in light transmittance was measured for 1 minute.

At this time, the positive voltage of +40V is applied until the light transmittance is 101% to 130% of the maximum light transmittance of the positive voltage of +10V.

Subsequently, after applying a voltage of −40V, the voltage is adjusted to 0V to convert the optical path control member to the privacy mode.

Subsequently, the change in light transmittance in the public mode was continuously measured for 5 minutes and 10 minutes while repeating the above positive and negative voltages.

### Example 2

After applying a positive voltage of +40V to the optical path control member in the initial mode to which no voltage is applied and reducing the voltage to a positive voltage of +10V to convert the optical path control member to public mode, and then the change in light transmittance was measured for 1 minute.

At this time, the positive voltage of +40V is applied until the light transmittance is 101% to 130% of the maximum light transmittance of the positive voltage of +10V.

Subsequently, after applying a voltage of −40V, the voltage is adjusted to 0V to convert the optical path control member to the privacy mode.

Subsequently, the change in light transmittance in the public mode was continuously measured for 90 minutes while repeating the above positive and negative voltages.

### COMPARATIVE EXAMPLE

After applying a positive voltage of +40V to the optical path control member in the initial mode to which no voltage is applied to convert the optical path control member to public mode, and then the change in light transmittance was measured for 10 minute.

Subsequently, after applying a voltage of −40V, the voltage is adjusted to 0V to convert the optical path control member to the privacy mode.

Subsequently, the change in light transmittance in the public mode was continuously measured for 5 minutes, 10 minutes, 30 minutes, 60 minutes, 30 minutes, 10 minutes, 5 minutes, and 1 minute while repeating the above positive and negative voltages.

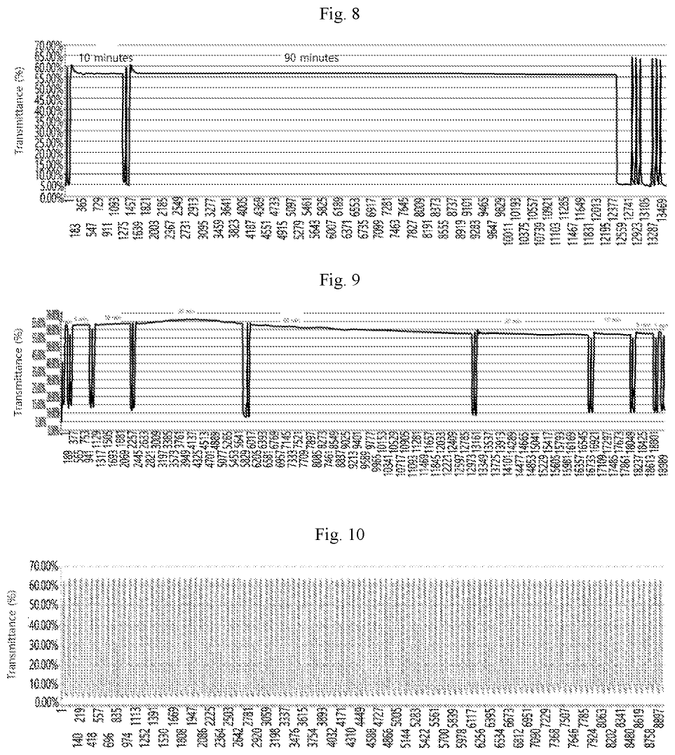

Referring to FIGS. 7 and 8, it can be seen that the optical path control member according to Examples 1 and 2 shows little change in light transmittance in the public mode while a holding voltage of 10V is applied. In particular, referring to FIG. 8, it can be seen that the change in light transmittance is less than 1% even after 90 minutes have elapsed.

On the other hand, referring to FIG. 9, it can be seen that the optical path control member according to the comparative example shows a very large change in light transmittance in the public mode while a voltage of 40V is applied.

That is, the optical path control member according to the embodiments may prevent aggregation of the light conversion particles by reducing the stress of the light conversion particles by the initial positive voltage and the holding positive voltage, and thereby it can be seen that the light transmittance is maintained for a long time in the public mode.

### Example 3

After applying a positive voltage of +40V for 20 seconds to the optical path control member in the initial mode to which no voltage is applied, the voltage was reduced to a positive voltage of +30 V and the voltage was applied for 10 seconds to convert the optical path control member to public mode.

Subsequently, after applying a voltage of −40V, the voltage is adjusted to 0V to convert the optical path control member to the privacy mode.

Subsequently, the power consumption of the optical path control member according to the magnitude of the positive and negative voltages was measured.

### Example 4

After applying a positive voltage of +40V for 20 seconds to the optical path control member in the initial mode to which no voltage is applied, the voltage was reduced to a positive voltage of +20 V and the voltage was applied for 10 seconds to convert the optical path control member to public mode.

Subsequently, after applying a voltage of −40V, the voltage is adjusted to 0V to convert the optical path control member to the privacy mode.

Subsequently, the power consumption of the optical path control member according to the magnitude of the positive and negative voltages was measured.

### Example 5

After applying a positive voltage of +40V for 20 seconds to the optical path control member in the initial mode to which no voltage is applied, the voltage was reduced to a positive voltage of +10 V and the voltage was applied for 10 seconds to convert the optical path control member to public mode.

Subsequently, after applying a voltage of −40V, the voltage is adjusted to 0V to convert the optical path control member to the privacy mode.

Subsequently, the power consumption of the optical path control member according to the magnitude of the positive and negative voltages was measured.

### Comparative Example 2

A positive voltage of +40 V was applied for 20 seconds to the optical path control member in the initial mode to which no voltage was applied to convert the optical path control member to public mode.

Subsequently, after applying a voltage of −40V, the voltage is adjusted to 0V to convert the optical path control member to the privacy mode.

Subsequently, the power consumption of the optical path control member according to the magnitude of the positive and negative voltages was measured.

### Comparative Example 3

After applying a positive voltage of +40V for 20 seconds to the optical path control member in the initial mode to which no voltage is applied, and then a positive voltage of +40 V was applied for 10 seconds to convert the optical path control member to public mode.

Subsequently, after applying a voltage of −40V, the voltage is adjusted to 0V to convert the optical path control member to the privacy mode.

Subsequently, the power consumption of the optical path control member according to the magnitude of the positive and negative voltages was measured.

TABLE 3

| | | Start | End | Start | End | Start | End |
|---|---|---|---|---|---|---|---|
| | | positive | positive | holding | holding | negative | negative |
| | | voltage | voltage | voltage | voltage | voltage | voltage |
| Example3 | Electric current(A) | 9.26*10⁻⁴ | 8.30*10⁻⁴ | 5.95*10⁻⁴ | 5.97*10⁻⁴ | −1.03*10⁻³ | −9.29*10⁻⁴ |
| | Voltage(V) | 40 | 40 | 30 | 30 | −40 | −40 |
| | Power | 3.70*10⁻² | 3.32*10⁻² | 1.78*10⁻² | 1.79*10⁻² | 4.13*10⁻² | 3.72*10⁻² |
| | consumption(W) | | | | | | |
| Example4 | Electric current(A) | 9.19*10⁻⁴ | 8.30*10⁻⁴ | 3.62*10⁻⁴ | 3.68*10⁻⁴ | −1.03*10⁻³ | −9.27*10⁻⁴ |
| | Voltage(V) | 40 | 40 | 20 | 20 | −40 | −40 |
| | Power | 3.68*10⁻² | 3.32*10⁻² | 7.24*10⁻³ | 7.37*10⁻³ | 4.12*10⁻² | 3.71*10⁻² |
| | consumption(W) | | | | | | |
| Example5 | Electric current(A) | 9.21*10⁻⁴ | 8.33*10⁻⁴ | 1.36*10⁻⁴ | 1.43*10⁻⁴ | −1.03*10⁻³ | −9.26*10⁻⁴ |
| | Voltage(V) | 40 | 40 | 10 | 10 | −40 | −40 |
| | Power | 3.68*10⁻² | 3.33*10⁻² | 1.36*10⁻³ | 1.43*10⁻³ | 4.12*10⁻² | 3.71*10⁻² |
| | consumption(W) | | | | | | |
| Comparative | Electric current(A) | 9.36*10⁻⁴ | 8.52*10⁻⁴ | — | — | −1.05*10⁻³ | −9.38*10⁻⁴ |
| Example2 | Voltage(V) | 40 | 40 | — | — | −40 | −40 |
| | Power | 3.74*10⁻² | 3.41*10⁻² | — | — | 4.20*10⁻² | 3.75*10⁻² |
| | consumption(W) | | | | | | |
| Comparative | Electric current(A) | 9.51*10⁻⁴ | 8.30*10⁻⁴ | — | — | −1.04*10⁻³ | −9.34*10⁻⁴ |
| Example3 | Voltage(V) | 40 | 40 | — | — | −40 | −40 |
| | Power | 3.80*10⁻² | 3.32*10⁻² | — | — | 4.15*10⁻² | 3.73*10⁻² |
| | consumption(W) | | | | | | |

TABLE 4

| | | Start | End | Start | End | Start | End |
|---|---|---|---|---|---|---|---|
| | | positive | positive | holding | holding | negative | negative |
| | | voltage | voltage | voltage | voltage | voltage | voltage |
| Example3 | Electric current(A) | 5.52*10⁻⁶ | 2.17*10⁻⁶ | −6.98*10⁻⁷ | 1.62*10⁻⁶ | −6.45*10⁻⁶ | −2.80*10⁻⁶ |
| | Voltage(V) | 40 | 40 | 30 | 30 | −40 | −40 |
| | Power | 2.21*10⁻⁴ | 8.66*10⁻⁵ | −2.07*10⁻⁵ | 4.85*10⁻⁵ | 2.58*10⁻⁴ | 1.12*10⁻⁴ |
| | consumption(W) | | | | | | |
| Example4 | Electric current(A) | 5.50*10⁻⁶ | 2.18*10⁻⁶ | −3.38*10⁻⁶ | 1.08*10⁻⁶ | −5.87*10⁻⁶ | −2.79*10⁻⁶ |
| | Voltage(V) | 40 | 40 | 20 | 20 | −40 | −40 |
| | Power | 2.20*10⁻⁴ | 8.72*10⁻⁵ | −6.76*10⁻⁵ | 2.15*10⁻⁵ | 2.35*10⁻⁴ | 1.11*10⁻⁴ |
| | consumption(W) | | | | | | |
| Example5 | Electric current(A) | 5.44*10⁻⁶ | 2.17*10⁻⁶ | −7.89*10⁻⁶ | 4.73*10⁻⁷ | −5.22*10⁻⁶ | −2.75*10⁻⁶ |
| | Voltage(V) | 40 | 40 | 10 | 10 | −40 | −40 |
| | Power | 2.18*10⁻⁴ | 8.69*10⁻⁵ | −7.89*10⁻⁵ | 4.73*10⁻⁶ | 2.09*10⁻⁴ | 1.10*10⁻⁴ |
| | consumption(W) | | | | | | |
| Comparative | Electric current(A) | 4.74*10⁻⁶ | 2.21*10⁻⁶ | — | — | −6.99*10⁻⁶ | −2.84*10⁻⁶ |
| Example2 | Voltage(V) | 40 | 40 | — | — | −40 | −40 |
| | Power | 1.90*10⁻⁴ | 8.86*10⁻⁵ | — | — | 2.79*10⁻⁴ | 1.14*10⁻⁴ |
| | consumption(W) | | | | | | |
| Comparative | Electric current(A) | 5.58*10⁻⁶ | 2.16*10⁻⁶ | — | — | −6.96*10⁻⁶ | −2.84*10⁻⁶ |
| Example3 | Voltage(V) | 40 | 40 | — | — | −40 | −40 |
| | Power | 2.23*10⁻⁴ | 8.62*10⁻⁵ | — | — | 2.78*10⁻⁴ | 1.14*10⁻⁴ |
| | consumption(W) | | | | | | |

Referring to Tables 3 and 4, it can be seen that the power consumption of the optical path control member according to Examples 3 to 5 is smaller than the power consumption of the optical path control member according to Comparative Examples 2 and 3.

That is, since the optical path control member according to Examples 3 to 5 drives the optical path control member with a lower voltage in the public mode than the optical path control member according to Comparative Example 2 and Comparative Example 3, it can be seen that the overall power consumption of the optical path control member can be reduced.

### Example 6

A positive voltage of +40 V was applied for 20 seconds to the optical path control member in the initial mode to which no voltage was applied to convert the optical path control member to public mode.

Subsequently, a voltage of −40 V is applied for 3 seconds to convert the optical path control member to the privacy mode.

Subsequently, a rest voltage step in which the 0V state is maintained for 5 seconds is performed so that no voltage is applied, and the mode is converted back to the initial mode.

After the public mode, the privacy mode, and the step of rest voltage are set to be one cycle, they are repeated over 100 cycles.

Subsequently, the change in light transmittance in the public mode is measured at each cycle.

### Comparative Example 4

A positive voltage of +40 V was applied for 20 seconds to the optical path control member in the initial mode to which no voltage was applied to convert the optical path control member to public mode.

Subsequently, a voltage of −40 V is applied for 3 seconds to convert the optical path control member to the privacy mode.

After the conversion between the public mode and the privacy mode is set as one cycle without the step of rest voltage, they are repeated over 100 cycles.

Subsequently, the change in light transmittance in the public mode is measured at each cycle.

Referring to FIG. 10, it can be seen that the light transmittance of the optical path control member according to Example 6 including the rest voltage step maintaining the 0V state after conversion from the public mode to the privacy mode has little change.

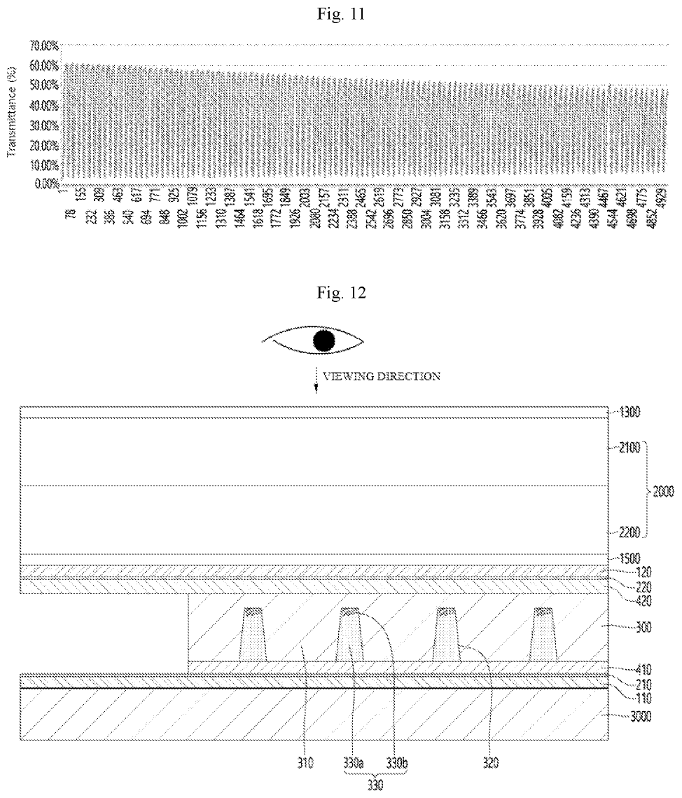

On the other hand, referring to FIG. 11, it can be seen that the transmittance of the optical path control member according to the comparative example in which the conversion from the public mode to the privacy mode is immediately followed by the conversion to the public mode decreases as the cycle is repeated.

That is, since the optical path control member according to the embodiment includes the idle voltage step, stress of the light conversion particles transmitted in the public mode and the privacy mode can be reduced. Accordingly, since aggregation of the light conversion particles may be prevented even if the cycle is repeated, the life of the optical path control member may be improved.

Hereinafter, referring to FIGS. 12 to 16, a display device to which an optical path control member according to an embodiment is applied will be described.

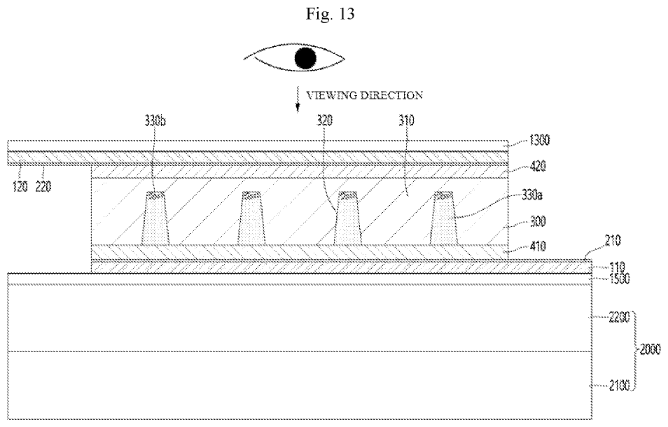

Referring to FIGS. 12 and 13, the optical path control member 1000 according to an embodiment may be disposed on or under a display panel 2000.

The display panel 2000 and the optical path control member 1000 may be disposed to be adhered to each other. For example, the display panel 2000 and the optical path control member 1000 may be adhered to each other via an adhesive layer 1500. The adhesive layer 1500 may be transparent. For example, the adhesive layer 1500 may include an adhesive or an adhesive layer including an optical transparent adhesive material.

The adhesive layer 1500 may include a release film. In detail, when adhering the optical path control member and the display panel, the optical path control member and the display panel may be adhered after the release film is removed.

The display panel 2000 may include a first′ substrate 2100 and a second′ substrate 2200. When the display panel 2000 is a liquid crystal display panel, the optical path control member may be formed under the liquid crystal panel. That is, when a surface viewed by the user in the liquid crystal panel is defined as an upper portion of the liquid crystal panel, the optical path control member may be disposed under the liquid crystal panel. The display panel 2000 may be formed in a structure in which the first′ substrate 2100 including a thin film transistor (TFT) and a pixel electrode and the second′ substrate 2200 including color filter layers are bonded to each other with a liquid crystal layer interposed therebetween.

In addition, the display panel 2000 may be a liquid crystal display panel of a color filter on transistor (COT) structure in which a thin film transistor, a color filter, and a black electrolyte are formed at the first′ substrate 2100 and the second′ substrate 2200 is bonded to the first′ substrate 2100 with the liquid crystal layer interposed therebetween. That is, a thin film transistor may be formed on the first′ substrate 2100, a protective film may be formed on the thin film transistor, and a color filter layer may be formed on the protective film. In addition, a pixel electrode in contact with the thin film transistor may be formed on the first′ substrate 2100. At this point, in order to improve an aperture ratio and simplify a masking process, the black electrolyte may be omitted, and a common electrode may be formed to function as the black electrolyte.

In addition, when the display panel 2000 is the liquid crystal display panel, the display device may further include a backlight unit 3000 providing light from a rear surface of the display panel 2000.

That is, as shown in FIG. 12, the optical path control member may be disposed under the liquid crystal panel and on the backlight unit 3000, and the optical path control member may be disposed between the backlight unit 3000 and the display panel 2000.

Alternatively, as shown in FIG. 13, when the display panel 2000 is an organic light emitting diode panel, the optical path control member may be formed on the organic light emitting diode panel. That is, when the surface viewed by the user in the organic light emitting diode panel is defined as an upper portion of the organic light emitting diode panel, the optical path control member may be disposed on the organic light emitting diode panel. The display panel 2000 may include a self-luminous element that does not require a separate light source. In the display panel 2000, a thin film transistor may be formed on the first′ substrate 2100, and an organic light emitting element in contact with the thin film transistor may be formed. The organic light emitting element may include an anode, a cathode, and an organic light emitting layer formed between the anode and the cathode. In addition, the second′ substrate 2200 configured to function as an encapsulation substrate for encapsulation may be further included on the organic light emitting element.

In addition, although not shown in drawings, a polarizing plate may be further disposed between the optical path control member 1000 and the display panel 2000. The polarizing plate may be a linear polarizing plate or an external light reflection preventive polarizing plate. For example, when the display panel 2000 is a liquid crystal display panel, the polarizing plate may be the linear polarizing plate. Further, when the display panel 2000 is the organic light emitting diode panel, the polarizing plate may be the external light reflection preventing polarizing plate.

In addition, an additional functional layer 1300 such as an anti-reflection layer, an anti-glare, or the like may be further disposed on the optical path control member 1000. Specifically, the functional layer 1300 may be adhered to one surface of the first substrate 110 of the optical path control member. Although not shown in drawings, the functional layer 1300 may be adhered to the first substrate 110 of the optical path control member via an adhesive layer. In addition, a release film for protecting the functional layer may be further disposed on the functional layer 1300.

Further, a touch panel may be further disposed between the display panel and the optical path control member.

It is illustrated in the drawings that the optical path control member is disposed at an upper portion of the display panel, but the embodiment is not limited thereto, and the optical path control member may be disposed at various positions such as a position in which light is adjustable, that is, a lower portion of the display panel, or between a second substrate and a first substrate of the display panel, or the like.

In addition, it is shown in the drawings that the light conversion unit of the optical path control member according to the embodiment is in a direction parallel or perpendicular to an outer surface of the second substrate, but the light conversion unit is formed to be inclined at a predetermined angle from the outer surface of the second substrate. Through this, a moire phenomenon occurring between the display panel and the optical path control member may be reduced.

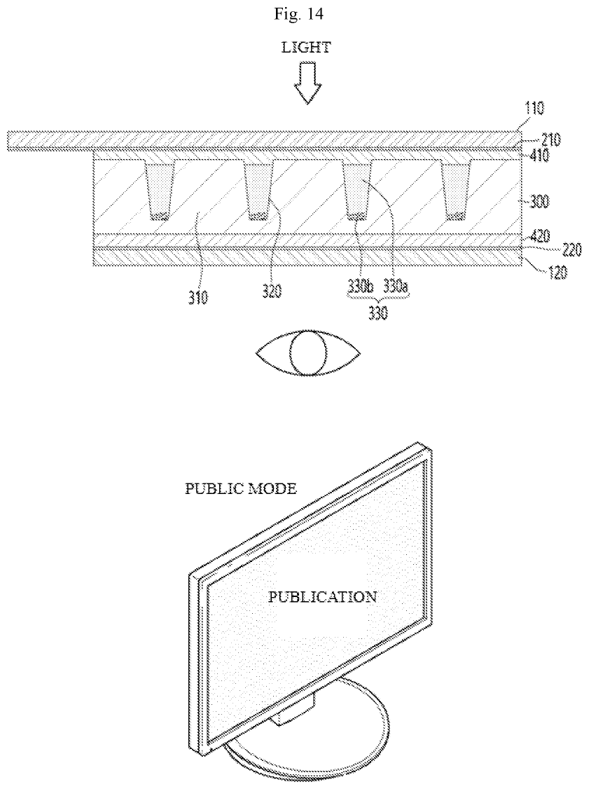

Referring to FIGS. 14 to 16, an optical path control member according to an embodiment may be applied to various display devices.

Referring to FIGS. 14 to 16, the optical path control member according to the embodiment may be applied to a display device that displays a display.

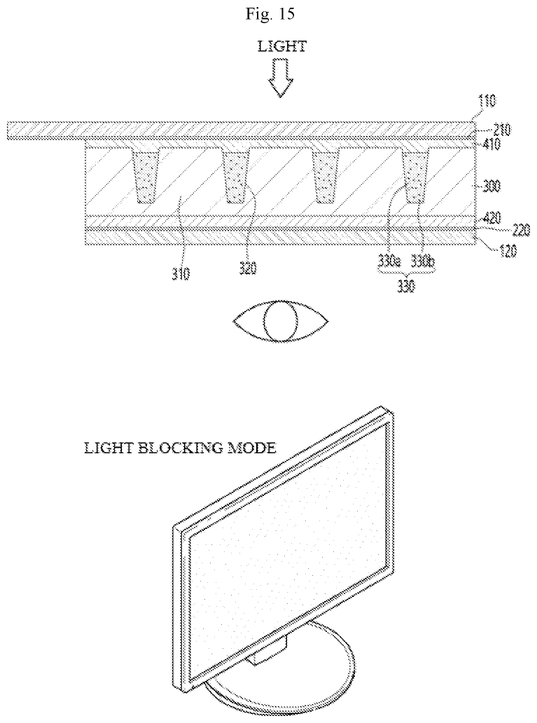

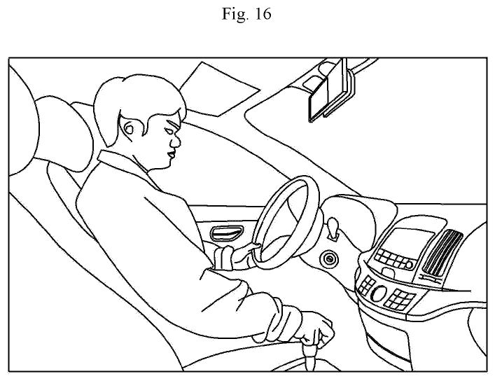

For example, when power is applied to the optical path control member as shown in FIG. 14, the accommodation part functions as the light transmitting part, so that the display device may be driven in the public mode, and when power is not applied to the optical path control member as shown in FIG. 15, the accommodation part functions as the light blocking part, so that the display device may be driven in the light blocking mode.

Accordingly, a user may easily drive the display device in a privacy mode or a normal mode according to application of power.

Light emitted from the backlight unit or the self-luminous element may move from the first substrate toward the second substrate. Alternatively, the light emitted from the backlight unit or the self-luminous element may also move from the second substrate toward the first substrate.

In addition, referring to FIG. 16, the display device to which the optical path control member according to the embodiment is applied may also be applied inside a vehicle.

For example, the display device including the optical path control member according to the embodiment may display a video confirming information of the vehicle and a movement route of the vehicle. The display device may be disposed between a driver seat and a passenger seat of the vehicle.

In addition, the optical path control member according to the embodiment may be applied to a dashboard that displays a speed, an engine, an alarm signal, and the like of the vehicle.

Further, the optical path control member according to the embodiment may be applied to a front glass (FG) of the vehicle or right and left window glasses.

The characteristics, structures, effects, and the like described in the above-described embodiments are included in at least one embodiment of the present invention, but are not limited to only one embodiment. Furthermore, the characteristic, structure, and effect illustrated in each embodiment may be combined or modified for other embodiments by a person skilled in the art. Accordingly, it is to be understood that such combination and modification are included in the scope of the present invention.

In addition, embodiments are mostly described above, but the embodiments are merely examples and do not limit the present invention, and a person skilled in the art may appreciate that several variations and applications not presented above may be made without departing from the essential characteristic of embodiments. For example, each component specifically represented in the embodiments may be varied. In addition, it should be construed that differences related to such a variation and such an application are included in the scope of the present invention defined in the following claims.

1. An optical path control member comprising:
a first substrate;
a first electrode disposed on the first substrate;
a second substrate disposed on the first substrate;
a second electrode disposed under the second substrate; and
a light conversion unit disposed between the first electrode and the second electrode,
wherein the light conversion unit includes a partition wall portion and an accommodating portion,
wherein the accommodating portion includes a dispersion liquid and light conversion particles dispersed in the dispersion liquid,
wherein the accommodating portion is driven in a public mode or a privacy mode depending on whether voltage is applied or not,
wherein the public mode includes applying an initial positive voltage and applying a holding positive voltage,
wherein the privacy mode includes applying a negative voltage,
wherein a step of applying the initial positive voltage, a step of applying the holding positive voltage, and the step of applying the negative voltage are sequentially performed,
wherein a magnitude of the initial positive voltage is greater than a magnitude of the holding positive voltage.

2. (canceled)

3. The optical path control member of claim 1, wherein an application time of the initial positive voltage is a time until light transmittance by the initial positive voltage reaches 70% to 130% of a maximum light transmittance of the holding positive voltage.

4. The optical path control member of claim 1, wherein the magnitude of the holding positive voltage varies according to a target transmittance.

5. The optical path control member of claim 1, wherein the magnitude of the holding positive voltage is 5% to 90% of the magnitude of the initial positive voltage.

6. The optical path control member of claim 1, wherein the holding positive voltage has a voltage magnitude in which a maximum light transmittance of the holding positive voltage is 70% or more of a maximum light transmittance of the initial positive voltage.

7. The optical path control member of claim 13,
wherein the magnitude of the first holding positive voltage is smaller than the magnitude of the initial positive voltage; and
wherein the magnitude of the second holding positive voltage is smaller than the magnitude of the first holding positive voltage.

8. The optical path control member of claim 1, wherein the holding positive voltage includes a first holding positive voltage and a second holding positive voltage,
wherein a magnitude of the first holding positive voltage is smaller than the magnitude of the initial positive voltage;
wherein a magnitude of the second holding positive voltage is greater than the magnitude of the first holding positive voltage.

9. The optical path control member of claim 1, wherein the privacy mode further includes applying a rest voltage after applying the negative voltage.

10. A display device comprising:
a panel including at least one of a display panel and a touch panel; and
the optical path control member of claim 1, which is disposed on or under the panel.

11. The optical path control member of claim 4, wherein as the target transmittance increases, the holding positive voltage increases; and as the target transmittance decreases, the holding positive voltage decreases.

12. The optical path control member of claim 1, wherein the holding positive voltage has a voltage magnitude in which a maximum light transmittance of the holding positive voltage is 70% to 99% of a maximum light transmittance of the initial positive voltage.

13. The optical path control member of claim 1, wherein the holding positive voltage includes a first holding positive voltage and a second holding positive voltage,
wherein a magnitude of the first holding positive voltage is different from a magnitude of the second holding positive voltage.

14. The optical path control member of claim 1, wherein the privacy mode includes applying a pulse voltage.

15. The optical path control member of claim 13, wherein the rest voltage is 0V,
wherein the rest voltage is applied for 5 seconds or more.

16. The optical path control member of claim 1, wherein surfaces of the light conversion particles are negatively charged.
